(19) United States
(12) Patent Application Publication
(10) Pub. No.: US 2024/0090332 A1
(43) Pub. Date: Mar. 14, 2024

(54) THERMOELECTRIC CONVERSION ELEMENT, THERMOELECTRIC CONVERSION MODULE, AND THERMOELECTRIC CONVERSION ELEMENT PRODUCING METHOD

(71) Applicant: Panasonic Intellectual Property Management Co., Ltd., Osaka (JP)

(72) Inventors: TAKESHI KAWABE, Osaka (JP); YURIKO KANEKO, Nara (JP); TSUTOMU KANNO, Kyoto (JP); HIROMASA TAMAKI, Osaka (JP)

(21) Appl. No.: 18/515,335

(22) Filed: Nov. 21, 2023

Related U.S. Application Data
(63) Continuation of application No. PCT/JP2022/017564, filed on Apr. 12, 2022.

(30) Foreign Application Priority Data
Jun. 8, 2021 (JP) 2021-095574

(51) Int. Cl. H10N 10/853; H10N 10/01; H10N 10/82; H10N 10/855; H10N 19/00

(52) U.S. Cl. CPC H10N 10/853; H10N 10/01; H10N 10/82; H10N 10/855; H10N 19/00

(57) ABSTRACT

A thermoelectric conversion element includes a p-type thermoelectric conversion layer, a first metal layer, a second metal layer, a first bonding layer, and a second bonding layer. The thermoelectric conversion layer is composed of a p-type thermoelectric conversion material containing a Mg₃(Sb,Bi)₂-based alloy as a main phase and containing carbon. At least one of the first bonding layer or the second bonding layer contains Al and Si.

### BACKGROUND

### 1. Technical Field

The present disclosure relates to a thermoelectric conversion element, a thermoelectric conversion module, and a thermoelectric conversion element producing method.

### 2. Description of the Related Art

Thermoelectric conversion elements have been known. Thermoelectric conversion modules in which a p-type thermoelectric conversion element composed of a p-type thermoelectric conversion material is electrically coupled to an n-type thermoelectric conversion element composed of an n-type thermoelectric conversion material are used. The thermoelectric conversion module enables power generation to be realized on the basis of the temperature difference caused by thermal energy being introduced. To facilitate electrical coupling of the thermoelectric conversion element, a metal member may be bonded to an end surface portion of the thermoelectric conversion material in advance by using a bonding material or the like. Such a thermoelectric conversion element in which the end surface portion is the metal member is readily handled or assembled.

Japanese Unexamined Patent Application Publication No. 2000-091649 discloses a thermoelectric conversion element having a configuration in which a thermoelectric conversion material containing a CoSb₃-based alloy as a main phase is bonded to a Cu electrode by using an Al—Si-based bonding material.

International Publication No. 2020/003554 discloses a thermoelectric conversion element having a configuration in which an n-type thermoelectric conversion material containing a Mg₃(Sb,Bi)₂-based alloy as a main phase is bonded to a metal member composed of a CuZn alloy.

Japanese Unexamined Patent Application Publication No. 2019-207983 discloses an n-type thermoelectric conversion material containing a Mg₃(Sb,Bi)₂-based alloy as a main phase and containing carbon.

A. Bhardwaj et al., “Graphene boosts thermoelectric performance of a Zintl phase compound”, RSC Advances, 2015, 5, 11058 discloses a p-type thermoelectric conversion material containing an Sb-rich Mg₃(Sb,Bi)₂-based alloy as a main phase and having a graphene nanosheet.

### SUMMARY

One non-limiting and exemplary embodiment provides a new thermoelectric conversion element.

In one general aspect, the techniques disclosed here feature a thermoelectric conversion element including a p-type thermoelectric conversion layer, a first metal layer, a second metal layer, a first bonding layer that bonds a first surface of the thermoelectric conversion layer to the first metal layer, and a second bonding layer that bonds a second surface of the thermoelectric conversion layer to the second metal layer, wherein the thermoelectric conversion layer is composed of a p-type thermoelectric conversion material containing a Mg₃(Sb,Bi)₂-based alloy as a main phase and containing carbon, and at least one of the first bonding layer or the second bonding layer contains Al and Si.

According to the present disclosure, a new thermoelectric conversion element can be provided.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram illustrating an example of a thermoelectric conversion element according to the present disclosure;

FIG. 2 is a schematic diagram illustrating a La₂O₃-type crystal structure according to the present disclosure;

FIG. 3 is a diagram illustrating a Raman spectral spectrum of a thermoelectric conversion material according to the present disclosure;

FIG. 4 is a schematic diagram illustrating an example of a thermoelectric conversion module according to the present disclosure;

FIG. 5 is a schematic diagram illustrating a modified example of the thermoelectric conversion module according to the present disclosure;

FIG. 6 is a schematic diagram illustrating an aspect of use of the thermoelectric conversion module according to the present disclosure;

FIG. 7 is a step diagram illustrating an example of a thermoelectric conversion material producing method according to the present disclosure;

FIG. 8 is a step diagram illustrating an example of a thermoelectric conversion element producing method according to the present disclosure;

FIG. 9 is a schematic diagram illustrating an example of a thermoelectric conversion element producing method according to the present disclosure;

FIG. 10 is a schematic diagram illustrating a modified example of the thermoelectric conversion element producing method according to the present disclosure;

FIG. 11 is an observation diagram of a thermoelectric conversion element produced in Example 1 after a durability test; and

FIG. 12 is an observation diagram of a thermoelectric conversion element produced in Comparative example 1 after a durability test.

### DETAILED DESCRIPTIONS

### Underlying Knowledge Forming Basis of the Present Disclosure

A thermoelectric conversion material containing a Mg₃(Sb,Bi)₂-based alloy as a main phase has high thermoelectric conversion characteristics up to about 400° C. On the other hand, the thermoelectric conversion material containing a Mg₃(Sb,Bi)₂-based alloy as a main phase deteriorates at higher than or equal to 527° C. due to decomposition of a compound, and the thermoelectric conversion characteristics deteriorate.

That is, it is desirable that the thermoelectric conversion element including the thermoelectric conversion material containing a Mg₃(Sb,Bi)₂-based alloy as a main phase be used at higher than or equal to 400° C. to realize high thermoelectric conversion characteristics and be used at a temperature of less than or equal to 520° C. at which the durability against decomposition is ensured.

Therefore, the criteria for selection of the bonding material used for producing the thermoelectric conversion element are that the heat resistance is ensured up to the upper limit of the operation temperature of the element and that bonding can be performed at lower than or equal to 520° C. at which the element does not deteriorate.

According to the research by the present inventors, an AlSi alloy was found as a bonding material which satisfies the criteria for selection. A thermoelectric conversion element including the bonding material composed of the AlSi alloy and the thermoelectric conversion material containing a Mg₃(Sb,Bi)₂-based alloy as a main phase had low resistance at room temperature and favorable initial characteristics. However, it was found that the thermoelectric conversion element including the bonding material composed of the AlSi alloy and the thermoelectric conversion material containing a Mg₃(Sb,Bi)₂-based alloy as a main phase was decomposed when being held in the air under the condition of 450° C. which is an operating temperature. Consequently, when the AlSi alloy is used as a bonding material, a contrivance for suppressing the thermoelectric conversion element that includes the thermoelectric conversion material containing a Mg₃(Sb,Bi)₂-based alloy as a main phase from being decomposed is further required.

Japanese Unexamined Patent Application Publication No. 2000-091649 discloses the thermoelectric conversion element having a configuration in which a thermoelectric conversion material containing a CoSb₃-based alloy as a main phase is bonded to a Cu electrode by using an Al—Si-based bonding material. However, there is no report with respect to the thermoelectric conversion element being decomposed due to the Al—Si-based alloy being used.

International Publication No. 2020/003554 discloses the thermoelectric conversion element having a configuration in which an n-type thermoelectric conversion material containing a Mg₃(Sb,Bi)₂-based alloy as a main phase is bonded to a metal member composed of a CuZn alloy. However, there is no report with respect to a thermoelectric conversion element including the AlSi alloy serving as a bonding material and the thermoelectric conversion material containing a Mg₃(Sb,Bi)₂-based alloy as a main phase.

Japanese Unexamined Patent Application Publication No. 2019-207983 discloses a thermoelectric conversion material containing an n-type Mg₃(Sb,Bi)₂-based alloy as a main phase and containing carbon. However, there is no report with respect to a thermoelectric conversion material containing, as a main phase, a p-type Mg₃(Sb,Bi)₂-based alloy containing carbon.

A. Bhardwaj et al., “Graphene boosts thermoelectric performance of a Zintl phase compound”, RSC Advances, 2015, 5, 11058 discloses a p-type thermoelectric conversion material containing an Sb-rich Mg₃(Sb,Bi)₂-based alloy as a main phase and having a graphene nanosheet. However, there is no report with respect to the thermoelectric conversion element being decomposed due to the Al—Si-based alloy being used.

According to the further research by the present inventors, it is considered that the n-type thermoelectric conversion element including the thermoelectric conversion material containing the n-type Mg₃(Sb,Bi)₂-based alloy as a main phase and the AlSi alloy disclosed in International Publication No. 2020/003554 or Japanese Unexamined Patent Application Publication No. 2019-207983 is unable to function as an element. The reason therefor is that Si in the AlSi alloy reacts with Mg to produce MgSi, a Mg defect is caused, and a p-type tends to result.

It was found on the basis of these examinations that carbon being contained in the thermoelectric conversion material containing a Mg₃(Sb,Bi)₂-based alloy as a main phase enables the thermoelectric conversion element including the bonding material composed of the AlSi alloy and the thermoelectric conversion material containing a Mg₃(Sb,Bi)₂-based alloy as a main phase to be suppressed from being decomposed in the air at 450° C. As a result, the thermoelectric conversion element including the bonding material composed of the AlSi alloy and the thermoelectric conversion material containing a Mg₃(Sb,Bi)₂-based alloy as a main phase can be stably obtained even under the condition of a high temperature of higher than or equal to 400° C. and lower than or equal to 520° C. Embodiment according to the present disclosure

The embodiment according to the present disclosure will be described below with reference to the drawings.

### Thermoelectric Conversion Element

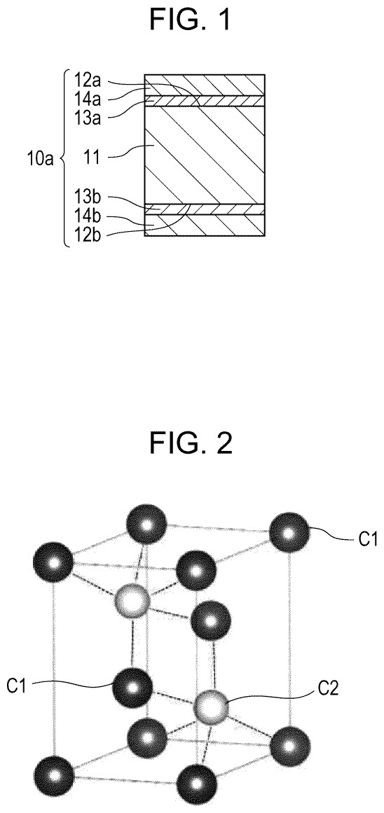

FIG. 1 is a schematic diagram illustrating an example of a thermoelectric conversion element according to the embodiment of the present disclosure. A thermoelectric conversion element 10a illustrated in FIG. 1 includes a thermoelectric conversion layer 11, a first metal layer 14a, a second metal layer 14b, a first bonding layer 13a, and a second bonding layer 13b. The first bonding layer 13a bonds a first surface 12a of the thermoelectric conversion layer 11 to the first metal layer 14a. The second bonding layer 13b bonds a second surface 12b of the thermoelectric conversion layer 11 to the second metal layer 14b.

As illustrated in FIG. 1, the shape of the thermoelectric conversion element 10a is, for example, a rectangular parallelepiped. In this regard, the shape of the thermoelectric conversion element 10a may be the shape of, for example, a cube, another prism, a circular cylinder, or a circular column provided that the shape is a three-dimensional shape capable of forming a layer.

### Thermoelectric Conversion Layer

The thermoelectric conversion layer 11 is a middle layer portion of the thermoelectric conversion element 10a, and the thickness of the thermoelectric conversion element 10a is, for example, greater than or equal to 0.5 mm and less than or equal to 5.0 mm. In other words, the thickness of the thermoelectric conversion element 10a satisfies, for example, a mathematical formula 0.5 mm≤tE≤5.0 mm. Herein, tE represents the thickness of the thermoelectric conversion element 10a according to the present disclosure.

The thermoelectric conversion layer 11 is composed of a thermoelectric conversion material containing, as a main phase, an alloy that contains Mg and at least one of Sb or Bi and containing carbon. The thermoelectric conversion material according to the present disclosure is a p-type thermoelectric conversion material. The contents of Mg, Sb, and Bi in the thermoelectric conversion material can be determined on the basis of, for example, X-ray diffractometry (XRD) or SEM-EDX, which is combination of a scanning electron microscope (SEM) and energy dispersive X-ray spectroscopy (EDX).

In this regard, it is sufficient that the thermoelectric conversion material is a thermoelectric conversion material containing, as a main phase, an alloy that contains Mg and at least one of Sb or Bi, and a subphase composed of another alloy may be contained.

The thermoelectric conversion material according to the present disclosure contains, for example, a Mg₃(Sb,Bi)₂-based alloy as a main phase. The Mg₃(Sb,Bi)₂-based alloy includes Mg₃(Sb,Bi)₂ and materials in which a portion of elements of Mg₃(Sb,Bi)₂ is substituted with another element. When the Mg₃(Sb,Bi)₂-based alloy is a material in which a portion of elements of Mg₃(Sb,Bi)₂ is substituted with another element, the content of the other element is less than the Mg content on an amount of substance basis and is less than the sum of the Sb content and the Bi content.

It is desirable that the Mg₃(Sb,Bi)₂-based thermoelectric conversion material be used at a temperature of lower than or equal to 520° C. at which the durability against decomposition is ensured.

The Mg₃(Sb,Bi)₂-based thermoelectric conversion material having an Sb content greater than a Bi content (that is, Sb-rich) is expected to have high thermoelectric conversion characteristics in a temperature range of higher than or equal to 400° C. Therefore, the operation temperature range of the Sb-rich Mg₃(Sb,Bi)₂-based thermoelectric conversion material is preferably higher than or equal to 300° C. and lower than or equal to 520° C., more preferably higher than or equal to 350° C. and lower than or equal to 520° C., and further preferably higher than or equal to 400° C. and lower than or equal to 520° C. In other words, the operation temperature range t1 of the Sb-rich Mg₃(Sb,Bi)₂-based thermoelectric conversion material preferably satisfies the condition of 300° C.≤t1≤520° C., more preferably satisfies the condition of 350° C.≤t1≤520° C., and further preferably satisfies the condition of 400° C.≤t1≤520° C.

On the other hand, the Mg₃(Sb,Bi)₂-based thermoelectric conversion material having a Bi content greater than an Sb content (that is, Bi-rich) is expected to have high thermoelectric conversion characteristics even in a temperature range of, for example, lower than 400° C. Therefore, the operation temperature range of the Bi-rich Mg₃(Sb,Bi)₂-based thermoelectric conversion material is preferably higher than or equal to 200° C. and lower than or equal to 520° C., more preferably higher than or equal to 300° C. and lower than or equal to 520° C., and further preferably higher than or equal to 300° C. and lower than or equal to 500° C. In other words, the operation temperature range t2 of the Bi-rich Mg₃(Sb,Bi)₂-based thermoelectric conversion material preferably satisfies the condition of 200° C.≤t2≤520° C., more preferably satisfies the condition of 300° C.≤t1≤520° C., and further preferably satisfies the condition of 300° C.≤t2≤500° C.

When the Mg₃(Sb,Bi)₂-based alloy is a main phase of the composition of the thermoelectric conversion material according to the present disclosure, for example, a subphase composed of another alloy may be contained.

The composition of the thermoelectric conversion material according to the present disclosure is denoted by, for example, Formula (1): Mg₃₋ₘAₓSb_{2-z}Bi_{z}.

A in Formula (1) contains at least one element species selected from the group consisting of Na, Li, and Ag.

The value of m in Formula (1) is preferably greater than or equal to −0.39 and less than or equal to 0.42, more preferably within the range of greater than or equal to −0.39 and less than or equal to 0.30, and further preferably within the range of greater than or equal to −0.30 and less than or equal to 0.20. In other words, the value of m preferably satisfies a mathematical formula −0.39≤m≤0.42, more preferably satisfies a mathematical formula −0.39≤m≤0.30, and further preferably satisfies a mathematical formula −0.30≤m≤0.20.

The value of x in Formula (1) is preferably within the range of greater than 0 and less than or equal to 0.12, more preferably within the range of greater than 0 and less than or equal to 0.10, and further preferably within the range of greater than or equal to 0.001 and less than or equal to 0.05. In other words, the value of x preferably satisfies a mathematical formula 0<x≤0.12, more preferably satisfies a mathematical formula 0<x≤0.10, and further preferably satisfies a mathematical formula 0.001<x≤0.05.

The value of z in Formula (1) is preferably within the range of greater than or equal to 0 and less than or equal to 2.0, more preferably within the range of greater than or equal to 0.01 and less than 2.0, and further preferably within the range of greater than or equal to 0.5 and less than 2.0. In other words, the value of z preferably satisfies a mathematical formula 0≤z≤2.0, more preferably satisfies a mathematical formula 0.01≤z<2.0, and further preferably satisfies a mathematical formula 0.5≤z<2.0.

Regarding each element, an error of about 10% of the prepared composition is allowable on account of preparation.

The thermoelectric conversion material according to the present disclosure has a La₂O₃-type crystal structure.

FIG. 2 is a schematic diagram illustrating a La₂O₃-type crystal structure. The thermoelectric conversion material according to the present disclosure may be single-crystalline or polycrystalline. When the thermoelectric conversion material according to the present disclosure is composed of a plurality of crystal grains, each crystal grain constituting the thermoelectric conversion material has a La₂O₃-type crystal structure. The La₂O₃-type crystal structure of the thermoelectric conversion material according to the present disclosure is clarified by X-ray diffraction measurement. As a result of the X-ray diffraction measurement, Mg is located at a C1 site, and at least one element of Sb or Bi is located at a C2 site. The C1 site and the C2 site form a bond illustrated by the dotted line in FIG. 2.

### Metal Layer

The first metal layer 14a and the second metal layer 14b illustrated in FIG. 1 are end surface portions of the thermoelectric conversion element 10a. The thickness of each of the first metal layer 14a and the second metal layer 14b is, for example, greater than or equal to 0.005 mm and less than or equal to 0.3 mm and may be greater than or equal to 0.005 mm and less than or equal to 0.2 mm. In other words, the thickness of each of the first metal layer 14a and the second metal layer 14b satisfies, for example, a mathematical formula 0.005 mm≤tM≤0.3 mm or a mathematical formula 0.005 mm≤tM≤0.2 mm. Herein, tM represents the thickness of each of the first metal layer 14a and the second metal layer 14b. The thicknesses of the two layers may be the same or may differ from each other.

The first metal layer 14a according to the present disclosure is not limited to a specific material. The first metal layer 14a contains, for example, Cu or a Cu alloy.

The second metal layer 14b according to the present disclosure is not limited to a specific material. The second metal layer 14b contains, for example, Cu or a Cu alloy.

The first metal layer 14a and the second metal layer 14b may contain less than or equal to 1% of impurity on account of production. The impurity is, for example, a metal impurity such as Al, Fe, Co, or Ni. As another example, the impurity is a nonmetal impurity such as oxygen or carbon.

### Bonding Layer

As illustrated in FIG. 1, the first bonding layer 13a is located between the first surface 12a of the thermoelectric conversion layer 11 and the first metal layer 14a. It is desirable that the first bonding layer 13a be in direct contact with the first surface 12a of the thermoelectric conversion layer 11. The first bonding layer 13a may be in direct contact with the first metal layer 14a or is not limited to being in direct contact with the first metal layer 14a due to a diffusion layer or the like being interposed. The second bonding layer 13b is located between the second surface 12b of the thermoelectric conversion layer 11 and the second metal layer 14b. It is desirable that the second bonding layer 13b be in direct contact with the second surface 12b of the thermoelectric conversion layer 11. The second bonding layer 13b may be in direct contact with the second metal layer 14b or is not limited to being in direct contact with the second metal layer 14b due to a diffusion layer or the like being interposed.

At least one of the first bonding layer or the second bonding layer contains Al and Si. The content of Si in at least one of the first bonding layer or the second bonding layer included in the thermoelectric conversion element according to the present disclosure is preferably greater than 0.0 at % and less than or equal to 25.0 at %, more preferably greater than or equal to 5.0 at % and less than or equal to 20.0 at %, and further preferably greater than or equal to 5.0 at % and less than or equal to 15.0 at %. In other words, at least one of the first bonding layer or the second bonding layer preferably satisfies a mathematical formula 0.0 at %<SC≤25.0 at %. Herein, SC represents the content of Si contained in at least one of the first bonding layer or the second bonding layer included in the thermoelectric conversion element according to the present disclosure. More preferably, a mathematical formula 5.0 at %≤SC≤20.0 at % is satisfied. Further preferably, a mathematical formula 5.0 at %≤SC≤15.0 at % is satisfied.

The thickness of each of the first bonding layer 13a and the second bonding layer 13b is, for example, greater than or equal to 0.01 mm and less than or equal to 0.3 mm. In other words, the thickness of each of the first bonding layer 13a and the second bonding layer 13b satisfies, for example, a mathematical formula 0.01 mm≤tB≤0.3 mm. Herein, tB represents the thickness of each of the first bonding layer 13a and the second bonding layer 13b according to the present disclosure.

An error of about 10% is allowable on account of production.

### Identification of Contained Carbon

Carbon contained in the thermoelectric conversion material according to the present disclosure is preferably a carbon material including at least one allotrope such as graphene or graphite. A carbon material containing, as a main component, graphite which is an allotrope is more preferable. As an example, carbon is contained in a grain, a grain boundary, or the like of each crystal grain constituting the thermoelectric conversion material according to the present disclosure.

The content of carbon in the thermoelectric conversion material according to the present disclosure is greater than or equal to 0.01 at % and less than or equal to 1.2 at %, more preferably greater than or equal to 0.1 at % and less than or equal to 1.0 at %, and further preferably greater than or equal to 0.1 at % and less than or equal to 0.8 at %. In other words, the thermoelectric conversion material according to the present disclosure preferably satisfies a mathematical formula 0.01 at %<CC≤1.2 at %. Herein, CC represents the content of carbon in the thermoelectric conversion element according to the present disclosure. More preferably, a mathematical formula 0.10 at %≤CC≤1.0 at % is satisfied. Further preferably, a mathematical formula 0.10 at %≤CC≤0.8 at % is satisfied.

That is, the mass ratio of the thermoelectric conversion material is preferably less than or equal to 100 relative to the mass ratio of carbon of 1. The mass ratio of carbon to the thermoelectric conversion material is more preferably 1: less than or equal to 80.

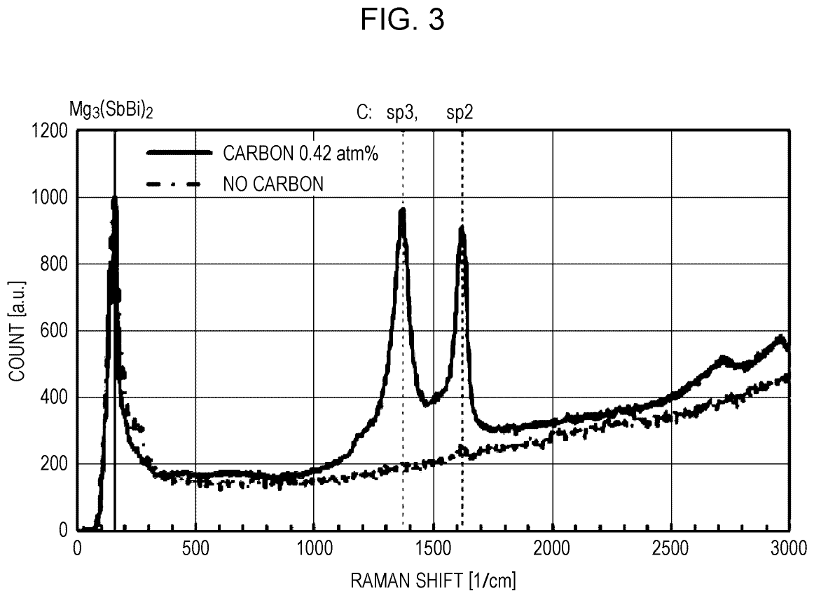

Carbon contained in the thermoelectric conversion material according to the present disclosure is identified by Raman spectroscopy. FIG. 3 illustrates the result of Raman spectroscopy for determining whether carbon is present. The wavelength of a light source used in the Raman spectroscopy is 488 nm. According to the Raman spectroscopy, a peak at about 180 cm⁻¹ illustrated in FIG. 3 is the peak indicating a Mg₃(Sb,Bi)₂ alloy. In this regard, each of two peaks at about 1,300 to 1,650 cm⁻¹ illustrated in FIG. 3 is a peak indicating carbon.

In FIG. 3, the solid line indicates the thermoelectric conversion material according to the present disclosure (legend: solid line). As illustrated in FIG. 3, regarding the thermoelectric conversion material according to the present disclosure, the peak intensity of the Mg₃(Sb,Bi)₂ alloy is assumed to be 1000, and when the peak intensity of at least one of the two carbon peaks is greater than or equal to 500, it is determined that carbon is contained. In other words, the thermoelectric conversion material according to the present disclosure satisfies Mathematical formula (M2) 0.5≤IC/IM. Herein, IC represents the peak intensity of the carbon in the Raman spectrum, and IM represents the peak intensity of the Mg₃(Sb,Bi)₂-based alloy in the Raman spectrum.

In FIG. 3, the broken line indicates the thermoelectric conversion material containing no carbon (legend: broken line). In this regard, a peak assigned to carbon may be observed with respect to the thermoelectric conversion material containing no carbon due to a sintering die made of carbon being used. In such an instance, when the peak intensity of the Mg₃(Sb,Bi)₂-based alloy is assumed to be 1000, the peak intensity of carbon is less than 500. In other words, the Mg₃(Sb,Bi)₂-based thermoelectric conversion material containing no carbon satisfies a mathematical formula 0.5>IC/IM.

Consequently, the thermoelectric conversion material containing no carbon can be differentiated from the thermoelectric conversion material containing carbon according to the present disclosure.

### Thermoelectric Conversion Module

A thermoelectric conversion module in which the p-type thermoelectric conversion element according to the present disclosure is electrically coupled to the n-type thermoelectric conversion element can be provided.

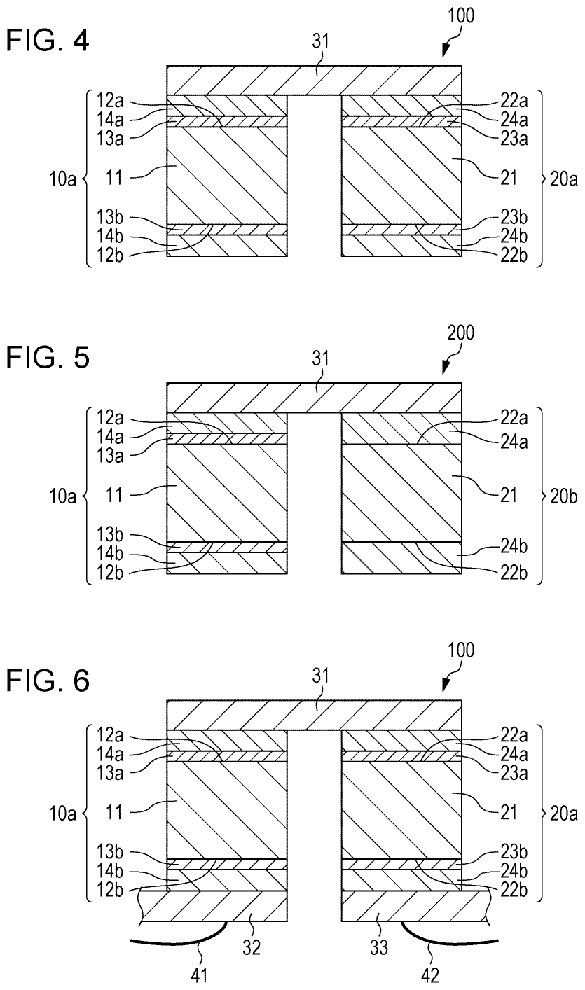

FIG. 4 illustrates an example of the thermoelectric conversion module according to the present disclosure. When the thermoelectric conversion element 10a illustrated in FIG. 1 is the p-type thermoelectric conversion element, as illustrated in FIG. 4, a thermoelectric conversion module 100 includes a p-type thermoelectric conversion element 10a and an n-type thermoelectric conversion element 20a. The p-type thermoelectric conversion element 10a and the n-type thermoelectric conversion element 20a are electrically coupled in series. The p-type thermoelectric conversion element 10a is electrically coupled to the n-type thermoelectric conversion element 20a through, for example, an outer electrode 31.

As illustrated in FIG. 4, the n-type thermoelectric conversion element 20a includes an n-type thermoelectric conversion layer 21, a third metal layer 24a, a fourth metal layer 24b, a third bonding layer 23a, and a fourth bonding layer 23b. The third bonding layer 23a bonds the third surface 22a of the n-type thermoelectric conversion layer 21 to the third metal layer 24a. The fourth bonding layer 23b bonds the fourth surface 22b of the n-type thermoelectric conversion layer 21 to the fourth metal layer 24b.

The n-type thermoelectric conversion layer 21 according to the present disclosure is composed of, for example, an n-type thermoelectric conversion material including, as a main phase, an alloy containing Mg and at least one of Sb or Bi. More specifically, the n-type thermoelectric conversion layer 21 is composed of, for example, an n-type thermoelectric conversion material containing a Mg₃(Sb,Bi)₂-based alloy as a main phase.

In the thermoelectric conversion module 100, the ratio of the number of Sb atoms to the number of Bi atoms contained in the p-type thermoelectric conversion material is not limited to being in accord with that in the n-type thermoelectric conversion material, where the p-type thermoelectric conversion material and the n-type thermoelectric conversion material are paired. When the ratios of the number of atoms are in accord with each other, the difference in the thermal expansion coefficient between the p-type thermoelectric conversion material and the n-type thermoelectric conversion material tends to be small. Consequently, thermal stress generated in the thermoelectric conversion module tends to be decreased.

The composition of the n-type thermoelectric conversion material according to the present disclosure is not limited to a specific composition.

The composition of the n-type thermoelectric conversion material according to the present disclosure is denoted by, for example, Formula (3): Mg₃₊ₘRₐT_{b}X₂₋ₑZₑ.

In Formula (3), R includes at least one element species selected from the group consisting of Ca, Sr, Ba, and Yb.

In Formula (3), T includes at least one element species selected from the group consisting of Mn and Zn.

In Formula (3), X includes at least one element species selected from the group consisting of Sb and Bi.

In Formula (3), Z includes at least one element species selected from the group consisting of Se and Te.

In Formula (3), the value of m is greater than or equal to −0.39 and less than or equal to 0.42. In other words, the value of m satisfies a mathematical formula −0.39≤m≤0.42.

In Formula (3), the value of a is greater than or equal to 0 and less than or equal to 0.12. In other words, the value of a satisfies a mathematical formula 0≤a≤0.12.

In Formula (3), the value of b is greater than or equal to 0 and less than or equal to 0.48. In other words, the value of b satisfies a mathematical formula 0≤b≤0.48.

In Formula (3), the value of e is greater than or equal to 0.001 and less than or equal to 0.06. In other words, the value of e satisfies a mathematical formula 0.001≤e≤0.06.

The n-type thermoelectric conversion material according to the present disclosure can have any composition within the range of Formula (3).

That is, the n-type thermoelectric conversion material according to the present disclosure is desirably a thermoelectric conversion material containing a Mg₃(Sb,Bi)₂-based alloy as a main phase.

In the present disclosure, the n-type thermoelectric conversion material also has a La₂O₃-type crystal structure. In such an instance, the n-type thermoelectric conversion material may be single-crystalline or polycrystalline.

The third metal layer 24a and the fourth metal layer 24b are end surface portions of the n-type thermoelectric conversion element 20a. The thickness of each of the third metal layer 24a and the fourth metal layer 24b is, for example, greater than or equal to 0.005 mm and less than or equal to 2 mm. The thickness of the third metal layer 24a and the fourth metal layer 24b may be the same or may differ from each other.

The composition of the third metal layer 24a and the composition of the fourth metal layer 24b may be the same as the composition of the first metal layer 14a and the composition of the second metal layer 14b, respectively. In such an instance, electrical coupling to the outer electrode can be simplified.

FIG. 5 illustrates a modified example of the thermoelectric conversion module according to the present disclosure. When the thermoelectric conversion element 10a illustrated in FIG. 1 is the p-type thermoelectric conversion element, as illustrated in FIG. 5, in a thermoelectric conversion module 200, the p-type thermoelectric conversion element 10a is electrically coupled to the n-type thermoelectric conversion element 20b through the outer electrode 31.

The n-type thermoelectric conversion element 20b includes an n-type thermoelectric conversion layer 21, a third metal layer 24a, and a fourth metal layer 24b. As illustrated in FIG. 5, in the n-type thermoelectric conversion element 20b, the third surface 22a of the n-type thermoelectric conversion layer 21 is directly bonded to the third metal layer 24a. In the same manner, the fourth surface 22b of the n-type thermoelectric conversion layer 21 is directly bonded to the fourth metal layer 24b.

That is, in the thermoelectric conversion module according to the present disclosure, as the thermoelectric conversion module 100 in FIG. 4, both the p-type thermoelectric conversion material 10a and the n-type thermoelectric conversion element 20a may include the bonding layer. Regarding the thermoelectric conversion module according to the present disclosure, as the thermoelectric conversion module 200 in FIG. 5, only the p-type thermoelectric conversion element 10a may include the bonding layer.

FIG. 6 illustrates an aspect of use of the thermoelectric conversion module 100 according to the present disclosure. The p-type thermoelectric conversion element 10a is electrically coupled to the outer electrode 32 through the second metal layer 14b. On the other hand, the n-type thermoelectric conversion element 20a is electrically coupled to the outer electrode 33 through the fourth metal layer 24b. A first wiring line 41 and a second wiring line 42 are responsible for outputting the electric power generated in the p-type thermoelectric conversion element 10a and the n-type thermoelectric conversion element 20a to the outside, the first wiring line 41 is coupled to the outer electrode 32, and the second wiring line 42 is coupled to the outer electrode 33.

### Producing Method

### Thermoelectric Conversion Material Producing Method

The thermoelectric conversion material producing method is not limited to a specific method. The thermoelectric conversion material is produced by a producing method including, for example, energizing an alloy powder containing Mg, at least one of Sb or Bi, and carbon by a spark plasma sintering method (SPS) so as to sinter the alloy powder at a temperature higher than or equal to 500° C. The thermoelectric conversion material contains, as a main phase, an alloy that contains Mg and at least one of Sb or Bi, contains carbon, and is a p-type. More specifically, for example, the thermoelectric conversion material contains a Mg₃(Sb,Bi)₂-based alloy as a main phase, contains carbon, and is a p-type. The alloy powder is, for example, a polycrystalline powder. In the SPS, the alloy powder is introduced into, for example, a carbon die. A predetermined pressure is applied to the alloy powder during sintering. The magnitude of the pressure is, for example, 10 MPa to 100 MPa. The sintering temperature of the alloy powder during sintering is, for example, lower than a melting temperature of the alloy and is, for example, lower than or equal to 700° C. The energization time of the alloy powder during sintering is not limited to a specific value. The energization time is, for example, 2 minutes to 1 hour.

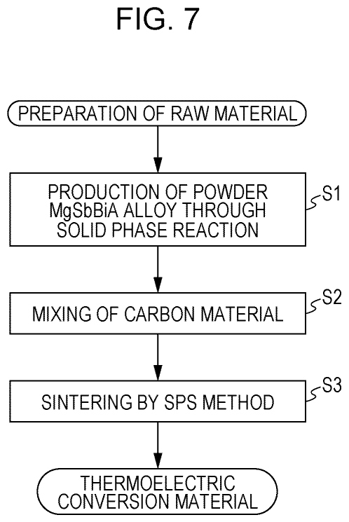

FIG. 7 is a step diagram illustrating the thermoelectric conversion material producing method according to the present disclosure.

FIG. 7 illustrates an example of the thermoelectric conversion material producing method according to the present disclosure in more detail. However, the thermoelectric conversion material producing method according to the present disclosure is not limited to the following example.

Regarding Step S1 in FIG. 7, a MgSbBiA alloy powder is obtained through a solid phase reaction of a Mg particle, a Sb particle, a Bi particle, and a doping material A powder, those of which are raw materials. An example of the solid phase reaction technique is a mechanical alloying method. In this regard, another technique such as a spark plasma sintering may be adopted as the solid phase reaction technique.

Subsequently, regarding Step S2, the MgSbBiA alloy powder and carbon are mixed. An example of the mixing technique is a mechanical alloying method. In this regard, another technique such as a ball mill method may be adopted as the mixing technique.

Finally, regarding Step S3, a precursor powder that is a mixture of MgSbBiA and carbon is subjected to sintering so as to obtain a single-crystalline material or a polycrystalline material of MgSbBiA and carbon. For example, a spark plasma sintering method or a hot press method can be adopted for sintering. The resulting sintered body may be used as a thermoelectric conversion material without being processed. In this regard, the resulting sintered body may be subjected to heat treatment. In such an instance, the heat-treated sintered body can also be used as a thermoelectric conversion material. Thermoelectric conversion element producing method and thermoelectric conversion module producing method

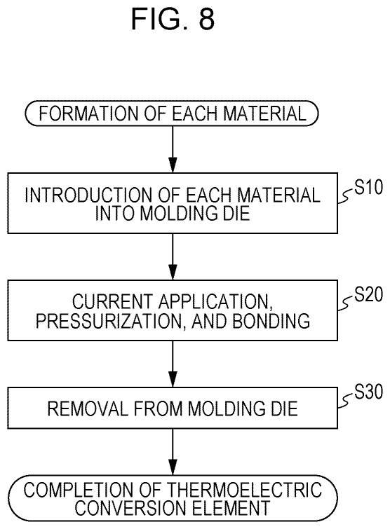

FIG. 8 is a step diagram illustrating a thermoelectric conversion element producing method according to the present disclosure.

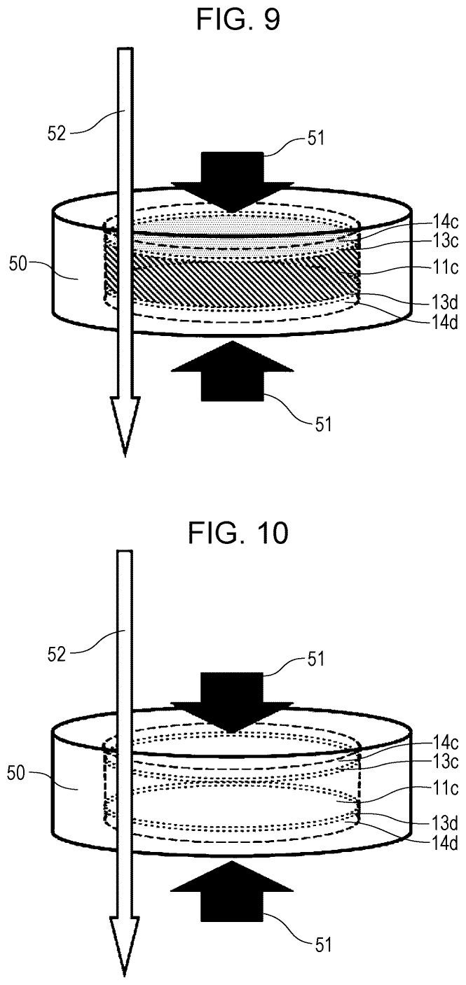

FIG. 9 illustrates an example of the thermoelectric conversion element producing method according to the present disclosure. The method will be described below. However, the thermoelectric conversion element producing method according to the present disclosure is not limited to the following example.

Regarding Step S10 in FIG. 8, a material 14c for forming the first metal layer, a material 13c for forming the first bonding layer, a material 11c for forming the thermoelectric conversion layer, a material 13d for forming the second bonding layer, and a material 14d for forming the second metal layer are introduced in this order into a molding die in FIG. 9. The introduction is performed in an inert atmosphere. The material 11c for forming the thermoelectric conversion layer is subjected to surface oxide film removal treatment after sintering. The sintering temperature can be higher than 500° C. by sintering the thermoelectric conversion material in advance and thereafter performing bonding of each layer. Since the thermoelectric conversion material is a polycrystalline material, when the sintering temperature is higher than 500° C., crystal grains become coarse due to generated polycrystalline material being kept at a high temperature. That is, grain growth occurs. The thermoelectric conversion material composed of grown crystal grains may have improved thermoelectric characteristics. The bonding temperature is desirably higher than or equal to 300° C. and lower than or equal to 500° C., more desirably higher than or equal to 400° C. and lower than or equal to 450° C., and further desirably higher than or equal to 410° C. and lower than or equal to 430° C. In other words, the bonding temperature in the thermoelectric conversion element producing method according to the present disclosure satisfies preferably 300° C.≤t≤500° C. Herein, t represents a bonding temperature for obtaining the above-described multilayer body. More preferably, 400° C.≤t≤450° C. is satisfied. Further preferably, 410° C.≤t≤430° C. is satisfied.

In this regard, the shape of the material constituting each layer may be contrived to increase the contact area. For example, when the thermoelectric conversion material constituting the thermoelectric conversion layer is sintered in advance, it is considered that the material constituting the first bonding layer and the second bonding layer is set to be powder-like, and the material constituting the first metal layer and the second metal layer is set to be plate-like, block-like, or powder-like. Devising the shape as described above increases the yield of the obtained thermoelectric conversion element when a thermoelectric conversion element substrate serving as a large thermoelectric conversion element is formed and the element substrate is cut into a plurality of thermoelectric conversion elements.

Subsequently, regarding Step S20, a bonded body is obtained by heating, at a predetermined temperature, and pressurizing the above-described materials introduced into the interior of the molding die 50. For example, in an inert atmosphere, sintering is performed by pressurizing the material in the pressurization directions 51 indicated by black arrows and applying a current 52 corresponding to the bonding temperature in the direction indicated by a white arrow. For example, a spark plasma sintering method or a hot press method can be adopted for the sintering method.

Finally, regarding Step S30, the thermoelectric conversion element that is a multilayer body bonded through sintering is removed from the molding die 50.

FIG. 10 illustrates a modified example of the thermoelectric conversion element producing method according to the present disclosure. In the producing method illustrated in FIG. 10, the precursor powder that is a mixture, before sintering, of a MgSbBiA powder and carbon is used as a material for forming the thermoelectric conversion layer.

That is, the material 14c for forming the first metal layer, the material 13c for forming the first bonding layer, the material 11c for forming the thermoelectric conversion layer, the material 13d for forming the second bonding layer, and the material 14d for forming the second metal layer are introduced in this order into a molding die 50. The introduction is performed in an inert atmosphere. Thereafter, bonding is performed by pressurizing the material in the pressurization directions 51 indicated by black arrows and applying a current 52 corresponding to the bonding temperature in the direction indicated by a white arrow. For example, a spark plasma sintering method or a hot press method can be adopted for sintering. According to the present modified example, sintering of the thermoelectric conversion material and bonding of the thermoelectric conversion layer and the metal layer can be performed in a single operation, and, therefore, the process can be simplified.

In the thermoelectric conversion element producing methods according to the present disclosure illustrated in FIG. 9 and FIG. 10, the material is bonded by being pressurized in the upward pressurization direction 51 and the downward pressurization direction 51 indicated by black arrows. The magnitude of pressurization in the upward direction is the same as that in the downward direction. The magnitude of pressurization when sintering of the thermoelectric conversion material and bonding of the thermoelectric conversion layer and the metal layer are performed separately from each other may be the same as or may differ from that when sintering of the thermoelectric conversion material and bonding of the thermoelectric conversion layer and the metal layer are simultaneously performed.

In FIG. 9 and FIG. 10, after the thermoelectric conversion layer, the first metal layer, and the second metal layer are bonded (Step S20), the interior of the thermoelectric conversion element may be homogenized by performing annealing treatment in an inert atmosphere to remove residual stress.

Assembling and production of the thermoelectric conversion module 100 or the thermoelectric conversion module 200 can be performed by a known method in which the n-type thermoelectric conversion element 20a or the n-type thermoelectric conversion element 20b, respectively, and the p-type thermoelectric conversion element 10a are used. Composition analysis and evaluation of thermoelectric conversion material after sintering and of each layer in thermoelectric conversion element after bonding Composition analysis and evaluation of the thermoelectric conversion material after sintering and of each layer in the thermoelectric conversion element after bonding can be performed. Examples of the technique of the composition analysis and evaluation include Raman spectroscopy, energy dispersive X-ray spectroscopy, X-ray photoelectron spectroscopy, and inductively coupled plasma emission spectroscopy. These techniques can also be applied to the thermoelectric conversion module after production.

There is no particular limitation regarding the application of the thermoelectric conversion element according to the present disclosure. The thermoelectric conversion element according to the present disclosure can be used for various applications including, for example, applications of the thermoelectric conversion element in the related art.

### Example 1

### Production of Thermoelectric Conversion Layer

In the interior of a glove box, 4 g of Mg_{2.99}Na_{0.01}Sb_{1.0}Bi_{1.0} produced through a solid phase reaction and 0.1 g of carbon powder (20 μm powder produced by Kojundo Chemical Laboratory Co., Ltd.) were weighed. The interior of the glove box was controlled to be an argon atmosphere until a thermoelectric conversion material was obtained. Subsequently, in the glove box, the weighed materials and stainless steel balls were sealed in a stainless steel container for mechanical alloying. Thereafter, a powder mixture was produced by using a room-temperature mill (Model: 8000D produced by SPEX). The resulting powder mixture was introduced into the sintering space of a carbon die and was subjected to powder compaction by using a carbon punch. The die was a sintering die having a diameter of 10 mm.

Subsequently, the die was housed in a chamber of a spark plasma sintering system (Model: SPS515S produced by Fuji Electronic Industrial Co., Ltd.). The chamber was controlled to be an argon atmosphere. A current was applied to the die by using the sintering system while a pressure of 50 MPa was applied to the material introduced in the die. After the die temperature reached 680° C. that was a sintering temperature due to application of the current, the temperature was maintained for 10 minutes. Thereafter, heating was stopped by the current being gradually decreased. After it was checked that the die temperature was decreased to room temperature, the sintered body was removed from the die. The surface oxide layer constituting the surface in contact with the sintering die of the sintered body that was the thermoelectric conversion material was polished, and the sintered body was washed with acetone. The thickness of the sintered body was about 5 mm.

### Bonding of Each Material

The thermoelectric conversion material subjected to polishing of the surface oxide layer, a Cu plate subjected to acetone washing, and an AlSi powder were transferred to the interior of the glove box. The Cu plate had a diameter of 10 mm and a thickness of 0.2 mm. The AlSi powder contained 88% of Al and 12% of Si on a mass basis. In the interior of the glove box, a Cu plate, the AlSi powder, the thermoelectric conversion material, the AlSi powder, and a Cu plate were introduced in this order into the sintering space of a carbon die (molding die), and powder compaction was performed by using a punch. The Cu plate was a material for forming the metal layer, and the AlSi powder was a material for forming the bonding layer.

The die was housed in the chamber of the spark plasma sintering system. The chamber was controlled to be an argon atmosphere. A current was applied to the die by using the sintering system while a pressure of 50 MPa was applied to the material introduced in the die. After the die temperature reached 400° C. that was a maximum sintering temperature due to application of the current, the temperature was maintained for 5 minutes. Thereafter, heating of the die was stopped by the current being gradually decreased. After the die temperature was decreased to room temperature, the thermoelectric conversion element substrate that was a multilayer body was removed from the die.

### Production of Thermoelectric Conversion Element

The sintered thermoelectric conversion element substrate was cut and machined into 4.3 mm×3.6 mm×2.7 mm pieces. The machined surface of the cut thermoelectric conversion element was polished and washed with acetone. The electrical resistance value of the thermoelectric conversion element was measured by using source measure unit(Model: 2400) produced by KEITHLEY in accordance with four-terminal sensing method. The result was 41 mΩ.

### Durability Test

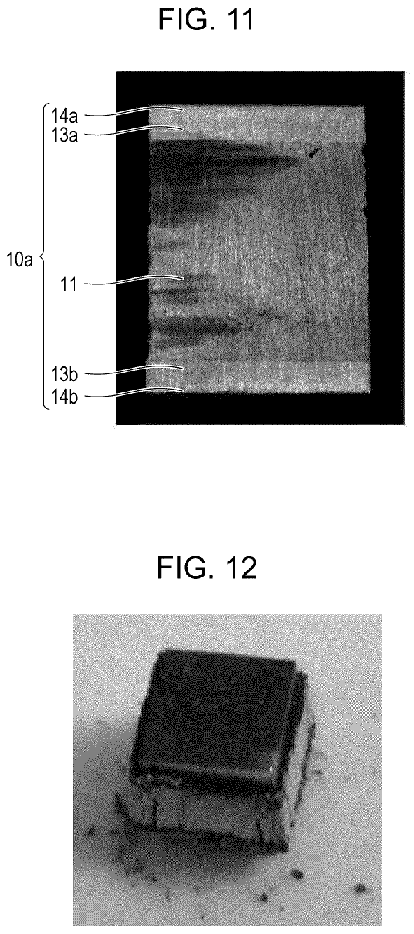

Regarding the durability test, the thermoelectric conversion element was heated in the air for 2 hours at 450° C., which was close to the upper limit of the operation temperature of the thermoelectric conversion element. FIG. 11 is an observation diagram of the thermoelectric conversion element produced in Example 1 after the durability test. Since the outermost surface of Cu was oxidized due to heating, the electrical resistance value was measured after an oxide layer was removed by polishing. As a result, the electrical resistance value of the thermoelectric conversion material after the durability test was 40 mΩ. Therefore, there was no significant change.

### Comparative Example 1

### Production of Thermoelectric Conversion Layer

A thermoelectric conversion material was produced in the manner akin to that in Example 1 except that 4 g of Mg_{2.99}Na_{0.01}Sb_{1.0}Bi_{1.0} produced through the solid phase reaction was weighed in the interior of the glove box.

### Bonding of Each Material

A thermoelectric conversion element substrate that was a multilayer body was obtained in the manner akin to that in Example 1.

### Production of Thermoelectric Conversion Element

The sintered thermoelectric conversion element substrate was cut and machined into 3.5 mm×3.4 mm×3.4 mm pieces. Thereafter, the electrical resistance value of the thermoelectric conversion element was measured in the manner akin to that in Example 1. The result was 30 mΩ.

### Durability Test

Regarding the durability test, in a similar manner to that in Example 1, the thermoelectric conversion element was heated in the air for 2 hours at 450° C., which was close to the upper limit of the operation temperature of the thermoelectric conversion element. As a result, the thermoelectric conversion element was decomposed. FIG. 12 is an observation diagram of the thermoelectric conversion element produced in Comparative example 1 after the durability test. That is, as illustrated in FIG. 12, the entire element was in the powder state of yellow and black, and the resistance could not be measured. The decomposed yellow powder was analyzed by X-ray diffraction (Model: bench-top-type X-ray diffractometer Aeris produced by Malvern Panalytical), and a peak conjectured to be bismuth oxide was observed.

The thermoelectric conversion element according to the present disclosure can be used for various applications including applications of the thermoelectric conversion element in the related art.

What is claimed is:

1. A thermoelectric conversion element comprising:
a p-type thermoelectric conversion layer;
a first metal layer;
a second metal layer;
a first bonding layer that bonds a first surface of the thermoelectric conversion layer to the first metal layer; and
a second bonding layer that bonds a second surface of the thermoelectric conversion layer to the second metal layer,
wherein the thermoelectric conversion layer is composed of a p-type thermoelectric conversion material containing a Mg₃(Sb,Bi)₂-based alloy as a main phase and containing carbon, and
at least one of the first bonding layer or the second bonding layer contains Al and Si.

2. The thermoelectric conversion element according to claim 1,
wherein the main phase of the thermoelectric conversion material in the thermoelectric conversion element has a composition denoted by Formula (1) Mg₃₋ₘAₓSb_{2-z}Bi_{z},
where A contains at least one selected from the group consisting of Na, Li, and Ag,
−0.39≤m≤0.42,
0<x≤0.12, and
0≤z≤2.0.

3. The thermoelectric conversion element according to claim 2,
wherein 0.5≤z<2.0.

4. The thermoelectric conversion element according to claim 2,
wherein 0.001≤x≤0.05.

5. The thermoelectric conversion element according to claim 1,
wherein the thermoelectric conversion material satisfies Mathematical formula (M2),
0.5≤IC/IM Mathematical formula (M2)
where IC represents a peak intensity of the carbon in a Raman spectrum, and
IM represents a peak intensity of the Mg₃(Sb,Bi)₂-based alloy in the Raman spectrum.

6. The thermoelectric conversion element according to claim 1,
wherein the thermoelectric conversion material satisfies Mathematical formula (M1),
0.01 at %≤CC≤1.2 at % Mathematical formula (M1)
where CC represents a content of the carbon in the thermoelectric conversion material.

7. The thermoelectric conversion element according to claim 1,
wherein the at least one of the first bonding layer or the second bonding layer in the thermoelectric conversion element satisfies Mathematical formula (M3),
0.0 at %≤SC≤25.0 at % Mathematical formula (M3)
Where SC represents a content of the Si in the at least one of the first bonding layer or the second bonding layer.

8. The thermoelectric conversion element according to claim 1,
Wherein the at least one of the first metal layer or the second metal layer in the thermoelectric conversion element contains Cu or a Cu alloy.

9. A thermoelectric conversion module in which a p-type thermoelectric conversion element is electrically coupled to an n-type thermoelectric conversion element,
wherein the p-type thermoelectric conversion element is the thermoelectric conversion element according to claim 1.

10. The thermoelectric conversion module according to claim 9,
wherein the n-type thermoelectric conversion element is provided with an n-type-thermoelectric conversion material containing, as a main phase, an alloy containing Mg and at least one of Sb or Bi.

11. A thermoelectric conversion element producing method comprising:
introducing a material for forming a first metal layer, a material for forming a first bonding layer, a material for forming a p-type thermoelectric conversion layer, a material for forming a second bonding layer, and a material for forming a second metal layer in this order into a molding die;
obtaining a multilayer body by heating, at a predetermined temperature, and pressurizing the material for forming the first metal layer, the material for forming the first bonding layer, the material for forming the thermoelectric conversion layer, the material for forming the second bonding layer, and the material for forming the second metal layer introduced into the interior of the molding die to cause bonding; and
removing the multilayer body from the molding die,
wherein the material for forming the thermoelectric conversion layer contains a Mg₃(Sb,Bi)₂-based alloy and carbon, and
the material for forming the first bonding layer and the material for forming the second bonding layer contain Al and Si.

12. The thermoelectric conversion element producing method according to claim 11,
wherein the predetermined temperature in the thermoelectric conversion element producing method satisfies Mathematical formula (M4),
300° C.≤t≤500° C. Mathematical formula (M4)
where t represents a bonding temperature for obtaining the multilayer body.
